(19) United States
(12) Patent Application Publication
(10) Pub. No.: US 2025/0323017 A1
(43) Pub. Date: Oct. 16, 2025

(54) MULTIPLE CHARGED-PARTICLE BEAM WRITING METHOD AND MULTIPLE CHARGED-PARTICLE BEAM WRITING APPARATUS

(71) Applicant: NuFlare Technology, Inc., Yokohama-shi (JP)

(72) Inventors: Hayato KIMURA, Sunto-gun (JP); Satoru HIROSE, Yokohama-shi (JP); Hideo INOUE, Miura-gun (JP); Kei HASEGAWA, Yokohama-shi (JP); Toshiki KIMURA, Yokohama-shi (JP); Tomoo MOTOSUGI, Yokohama-shi (JP); Shunsuke ISAJI, Kouza-gun (JP); Ryosuke UEBA, Yokohama-shi (JP)

(73) Assignee: NuFlare Technology, Inc., Yokohama-shi (JP)

(21) Appl. No.: 19/171,929

(22) Filed: Apr. 7, 2025

(30) Foreign Application Priority Data
Apr. 16, 2024 (JP) 2024-066242

(51) Int. Cl. H01J 37/317; H01J 37/04; H01J 37/147; H01J 37/304

(52) U.S. Cl. CPC H01J 37/3177; H01J 37/045; H01J 37/147; H01J 37/3045; H01J 2237/0435

(57) ABSTRACT

In one embodiment, a multiple charged-particle beam writing method includes emitting multiple charged-particle beams, switching predetermined beams of the multiple charged-particle beams between on and off using a plurality of blankers provided on a blanking aperture array substrate, and transferring, while moving a stage installed in a writing chamber, control data for on-off control of each beam of the multiple charged-particle beams to a control circuit of the blanking aperture array substrate to irradiate a writing target substrate placed on the stage with the multiple charged-particle beams based on the control data and write a pattern. The control circuit is operated during a period of beam non-irradiation in which the writing target substrate is not irradiated with the multiple charged-particle beams.

### CROSS REFERENCE TO RELATED APPLICATION

This application is based upon and claims benefit of priority from the Japanese Patent Application No. 2024-066242, filed on Apr. 16, 2024, the entire contents of which are incorporated herein by reference.

### FIELD

The present invention relates to a multiple charged-particle beam writing method and a multiple charged-particle beam writing apparatus.

### BACKGROUND

As LSI circuits are increasing in density, the required linewidths of circuits included in semiconductor devices become finer year by year. To form a desired circuit pattern on a semiconductor device, a method is employed in which a high-precision original pattern (a mask, or also called reticle when particularly used in a stepper or a scanner) formed in a light shielding film on a quartz is transferred to a wafer in a reduced manner by using a reduced-projection exposure apparatus. To produce such high-precision original patterns, so-called electron beam lithography technology is used, in which patterns are formed by exposing resist with an electron beam writing apparatus.

A writing apparatus that uses a multi-beam can emit more beams at one time than a writing apparatus that performs writing by a single electron beam, thus the throughput can be significantly improved. As a form of multi-beam writing apparatus, a multi-beam writing apparatus using a blanking aperture array substrate forms a multi-beam (a plurality of electron beams) by passing an electron beam emitted from an electron source through a shaping aperture array substrate having a plurality of openings. The multi-beam passes through corresponding blankers mentioned below of the blanking aperture array substrate. The blanking aperture array substrate has electrode pairs (blankers) for individually deflecting beams, and includes an opening for beam passage between each electrode pair. Blanking deflection is performed on the passing electron beam by controlling the electrode pair at the same electrical potential or at different electrical potentials. A beam deflected by a blanker is blocked, and an individual beam not deflected is emitted onto a sample.

A blanking aperture array substrate has a control circuit for on-off control of individual beams, and the temperature of the blanking aperture array substrate increases due to the current flowing through the control circuit in response to data transfer. There is a problem in that when the temperature of the blanking aperture array substrate increases, a shaping aperture array substrate is deformed by the radiation heat, the positions of the shaped beams fluctuate, and the writing accuracy decreases.

During the writing process, the amount of data transferred to the blanking aperture array substrate fluctuates, and thus the amount of heat generated by the blanking aperture array substrate is not constant. Even with a cooling system installed to cool the shaping aperture array substrate, it has been difficult to stabilize the temperature of the shaping aperture array substrate.

### BRIEF DESCRIPTION OF THE DRAWINGS

FIG. 1 is a schematic diagram of a multiple charged-particle beam writing apparatus according to an embodiment of the present invention.

FIG. 2 is a plan view of a shaping aperture array substrate.

FIG. 3 is a diagram for describing a writing region of a substrate.

FIG. 4 is a diagram for describing beam tracking control.

FIG. 5 is a schematic diagram of the configuration of a blanking aperture array substrate.

FIG. 6 is a diagram of the configuration of input-output circuits and a cell array circuit.

FIG. 7 is a schematic diagram of the configuration of an individual blanking mechanism.

FIG. 8A is a graph illustrating an example of changes in the temperature of a shaping aperture array substrate according to a comparative example, and FIG. 8B is a graph illustrating an example of changes in the temperature of the shaping aperture array substrate according to the present embodiment.

FIG. 9 is a diagram illustrating an example of the arrangement of on-state beams and off-state beams.

FIG. 10 is a diagram for describing a tracking cycle.

### DETAILED DESCRIPTION

In one embodiment, a multiple charged-particle beam writing method includes emitting multiple charged-particle beams, switching predetermined beams of the multiple charged-particle beams between on and off using a plurality of blankers provided on a blanking aperture array substrate, and transferring, while moving a stage installed in a writing chamber, control data for on-off control of each beam of the multiple charged-particle beams to a control circuit of the blanking aperture array substrate to irradiate a writing target substrate placed on the stage with the multiple charged-particle beams based on the control data and write a pattern. The control circuit is operated during a period of beam non-irradiation in which the writing target substrate is not irradiated with the multiple charged-particle beams.

Hereinafter, an embodiment of the present invention will be described based on the drawings. In the present embodiment, a configuration using an electron beam as an example of a charged particle beam will be described. The charged particle beam is not limited to the electron beam. For example, the charged particle beam may be an ion beam.

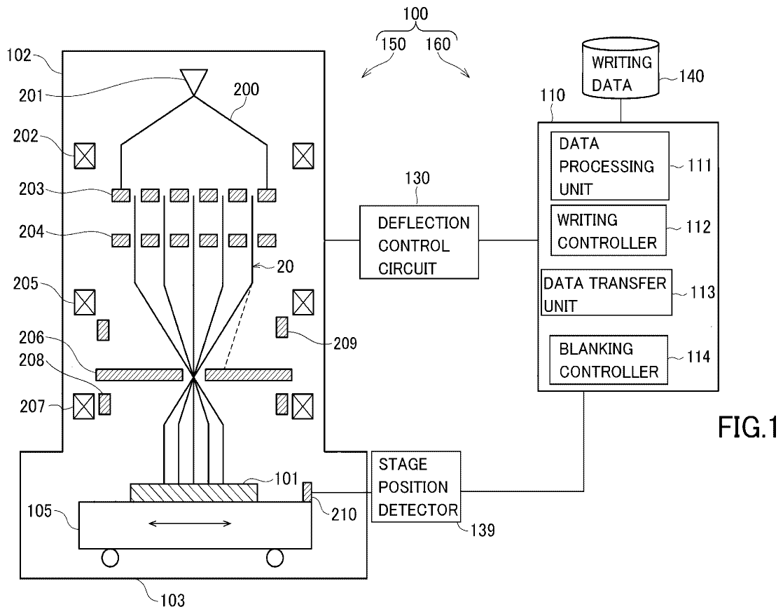

FIG. 1 is a schematic diagram of the configuration of a writing apparatus according to an embodiment. As illustrated in FIG. 1, a writing apparatus 100 includes a writing unit 150 and a control unit 160. The writing apparatus 100 is an example of a multiple charged-particle beam writing apparatus. The writing unit 150 includes an electron-optical column 102 and a writing chamber 103. In the electron-optical column 102, an electron gun 201, an illumination lens 202, a shaping aperture array substrate 203, a blanking aperture array substrate 204, a reduction lens 205, a limiting aperture member 206, an objective lens 207, a deflector 208, and a collective deflector 209 are arranged.

In the writing chamber 103, an XY stage 105 is arranged. On the XY stage 105, a substrate 101 used as a writing target is arranged. A resist that is to be exposed to an electron beam is applied onto the top surface of the substrate 101. The substrate 101 is, for example, a substrate to be processed into a mask (a mask blank) or a semiconductor substrate to be processed into semiconductor devices (a silicon wafer). A mirror 210 for stage position measurement is arranged on the XY stage 105.

A mark for drift measurement (not illustrated) is provided on the XY stage 105. A detector (not illustrated) is provided in the writing chamber 103 to detect reflected electrons from the mark. During drift measurement, the mark is scanned with an electron beam, the reflected electrons are detected by the detector, and the beam position is calculated from the change in the amount of reflected electrons.

The control unit 160 has a control computer 110, a deflection control circuit 130, a stage position detector 139, and a memory unit 140. Writing data is input from the outside and stored in the memory unit 140. In the writing data, information regarding multiple graphic patterns to be written is usually defined. Specifically, for each graphic pattern, a graphic code, coordinates, size, and so forth are defined.

The control computer 110 has a data processing unit 111, a writing controller 112, a data transfer unit 113, and a blanking controller 114. Each unit of the control computer 110 may be configured using hardware, such as electrical circuits, or software, such as a program that executes these functions in the control computer 110. Alternatively, each unit of the control computer 110 may be configured using a combination of hardware and software.

The stage position detector 139 emits a laser, receives reflected light from the mirror 210, and detects the position of the XY stage 105 using the principle of laser interferometry.

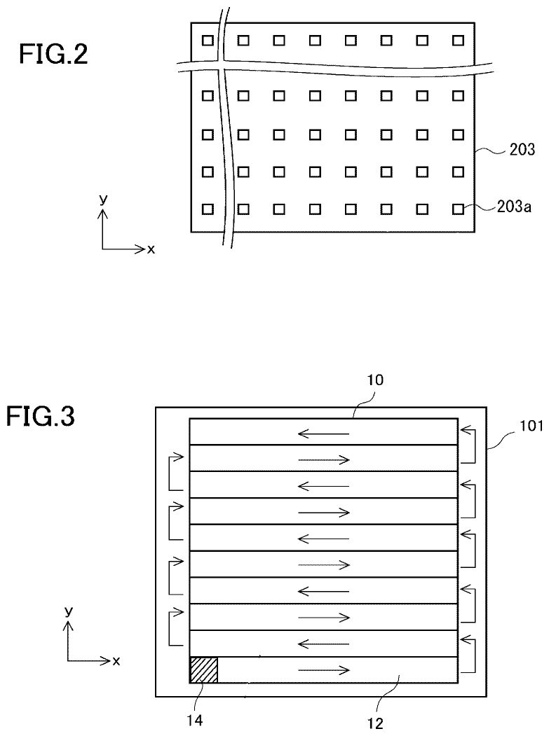

FIG. 2 is a schematic diagram of the configuration of the shaping aperture array substrate 203. As illustrated in FIG. 2, the shaping aperture array substrate 203 has multiple apertures 203a formed along the vertical direction (y-direction) and the horizontal direction (x-direction) at a predetermined array pitch. Each aperture 203a is formed, for example, in a rectangular or circular shape with (approximately) the same dimensions.

An electron beam 200 emitted from the electron gun 201 (an electron source) is caused to illuminate the entirety of the shaping aperture array substrate 203 almost vertically by the illumination lens 202. A portion of the electron beam 200 passes through the multiple apertures 203a in the shaping aperture array substrate 203 to form and emit multiple beams 20 constituted by a plurality of individual beams having rectangular shapes in cross-sectional view, for example.

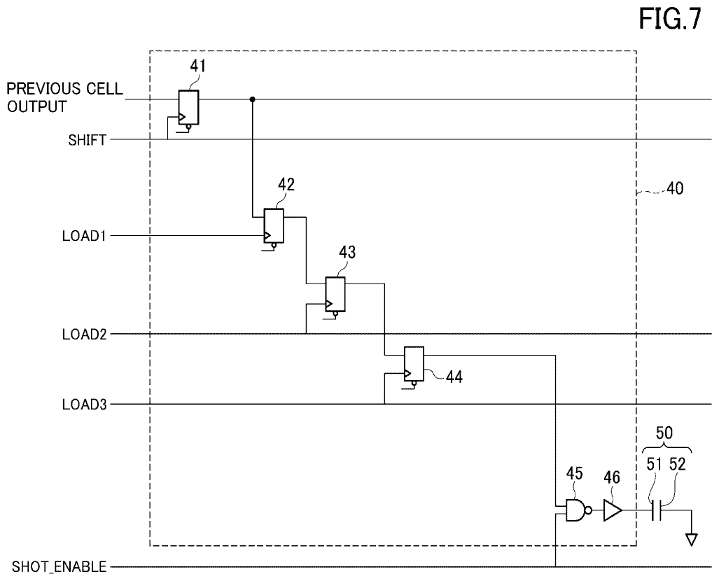

The blanking aperture array substrate 204 has beam pass-through holes formed so as to be aligned with the arrangement position of each aperture 203a in the shaping aperture array substrate 203. A blanker 50 (see FIG. 7) formed by a set of two electrodes 51 and 52 is arranged in each pass-through hole. By keeping the electrode 52 grounded to have ground potential and switching the other electrode 51 between the ground potential and a potential other than the ground potential, the deflection of the individual beam passing through the pass-through hole is switched between off and on to perform blanking control.

In a beam-on case, the opposing electrodes 51 and 52 of the blanker 50 are controlled to maintain the same potential, and the blanker 50 does not deflect the beam. In a beam-off case, the opposing electrodes 51 and 52 of the blanker 50 are controlled to maintain different potentials from each other, and the blanker 50 deflects the beam. The multiple blankers 50 can control the beams to be in the off state by performing blanking deflection on the corresponding beams out of the multiple beams that have passed through the multiple apertures 203a of the shaping aperture array substrate 203.

The multiple beams 20 that have passed through the blanking aperture array substrate 204 are reduced by the reduction lens 205 and proceed toward the central aperture formed in the limiting aperture member 206.

In this case, the individual beams that are controlled to be in the beam-off state are deflected by the blankers 50 and shielded by the limiting aperture member 206 because the individual beams travel along trajectories that pass outside the aperture of the limiting aperture member 206. In contrast, the individual beams that are controlled to be in the beam-on state are not deflected by the blankers 50 and pass through the aperture of the limiting aperture member 206. In this case, the beams ideally pass through the same point. The beam trajectories are adjusted with an alignment coil (not illustrated) so that this point is located within the central aperture of the limiting aperture member 206. In this manner, blanking control is performed by the blankers 50 activating and deactivating deflection, so that beam on-off control is performed.

The limiting aperture member 206 shields the individual beams that are deflected by a plurality of blankers 50 to be in the beam-off state. The multiple beams for one shot are then formed by the beams that have passed through the limiting aperture member 206 from when the beam is switched on until the beam is switched off.

The collective deflector 209 (a common blanker) is arranged between the blanking aperture array substrate 204 and the limiting aperture member 206 and can deflect all the multiple beams 20 in a collective manner, regardless of whether the beams have been on or off at the blankers 50.

The multiple beams that have passed through the limiting aperture member 206 are focused by the objective lens 207 to form a pattern image with a desired reduction ratio. The individual beams (all the multiple beams) that have passed through the limiting aperture member 206 are deflected in a collective manner in the same direction by the deflector 208. The desired positions on the substrate 101 are irradiated with the individual beams, so that the pattern is written.

FIG. 3 is a schematic diagram for describing an example of a region to be written. As illustrated in FIG. 3, a writing region 10 of the substrate 101 is virtually divided into multiple stripe regions 12, for example, having strip shapes with a predetermined width in the y-direction. In a case where a pattern is to be written on the writing region 10 using the writing apparatus 100, for example, the XY stage 105 is first moved to make an adjustment such that an irradiation region 14, which can be irradiated with a single shot of multiple beams 20, is located at a left end of the first stripe region 12 or a position further to the left of the left end, and writing is started. When writing is performed on the first stripe region 12, the XY stage 105 is moved in the −x-direction, for example, to proceed with writing, which is relatively performed in the +x-direction. The XY stage 105 is moved continuously at a constant speed, for example. After the writing on the first stripe region 12 is completed, the stage position is moved in the −y-direction, and now the XY stage 105 is moved in the +x-direction, for example, to perform writing, which is similarly performed in the −x-direction. This operation is repeated to perform writing in each of the stripe regions 12 in sequence. Writing while changing the direction in an alternating manner can reduce writing time. Note that writing does not have to be performed while changing the direction in an alternating manner, and it is also acceptable to proceed with writing in the same direction when writing is performed on each of the stripe regions 12.

In a case where the XY stage 105 is moving continuously, at least while the substrate 101 is being irradiated with the beams, the beam irradiation positions on the substrate 101 are controlled by the deflector 208 to follow the movement of the XY stage 105. The multiple beams with which irradiation is performed at once are ideally aligned on the substrate 101 at a pitch obtained by multiplying the array pitch of the multiple apertures 203a of the shaping aperture array substrate 203 by the desired reduction ratio described above.

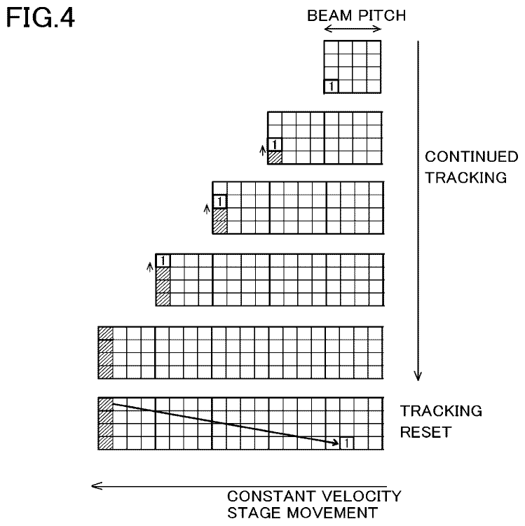

For example, as illustrated in FIG. 4, while the XY stage 105 is moving by a distance equivalent to four beam pitches, one beam writes four pixels in sequence (exposure). While four pixels are being written, the irradiation region 14 is caused to follow the movement of the XY stage 105 by the deflector 208 deflecting all the multiple beams 20 such that the relative position of the irradiation region 14 with respect to the substrate 101 is not shifted due to the movement of the XY stage 105. In other words, tracking control is performed.

In the example in FIG. 4, the pixel to be written is shifted three times from the initial position. After the fourth pixel is irradiated with the beam, the tracking position is reset to the tracking start position, where tracking control was initiated, by resetting the beam deflection for tracking control.

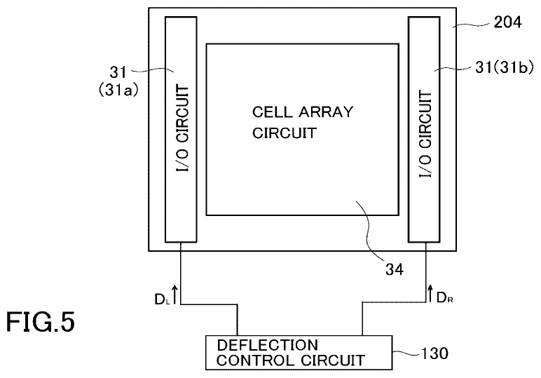

The blanking aperture array substrate 204, which performs blanking control on each of the multiple beams, has input-output circuits 31 (31a, 31b) and a cell array circuit 34 in which multiple blankers are provided, as illustrated in FIG. 5. The input-output circuits 31 receive control signals from the deflection control circuit 130.

The cell array circuit 34 is provided in the central portion of the blanking aperture array substrate 204, and the two input-output circuits 31a and 31b are provided across the cell array circuit 34. Data paths D_{L} and D_{R} for the control signals from the deflection control circuit 130 to the blanking aperture array substrate 204 are divided into two systems.

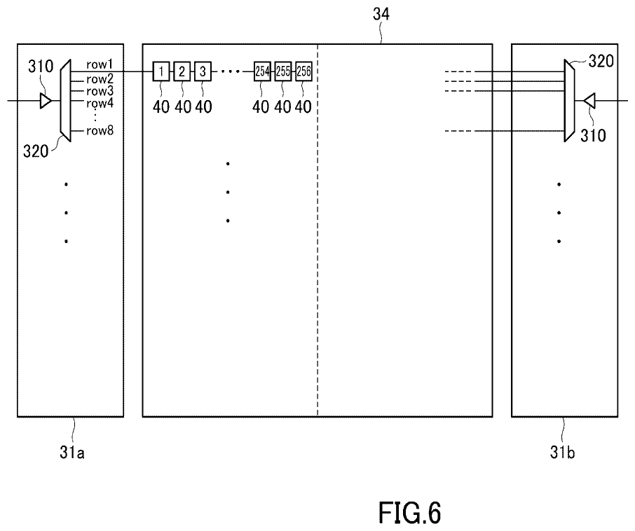

As illustrated in FIG. 6, the cell array circuit 34 has multiple cells that constitute individual blanking mechanisms 40. One individual blanking mechanism 40 corresponds to one blanker 50. The input-output circuits 31 convert the control signals received from the deflection control circuit 130 into beam on-off signals and then output the beam on-off signals to the cell array circuit 34. For example, the input-output circuit 31a outputs the beam on-off signal to the individual blanking mechanisms 40 arranged on one half of the cell array circuit 34, and the input-output circuit 31b outputs the beam on-off signal to the individual blanking mechanisms 40 arranged on the other half.

The input-output circuits 31 have multiple selectors 320 (demultiplexers). Each selector 320 receives, via an amplifier 310, irradiation time control data defining the irradiation time for each beam shot, and outputs the beam on-off signal from the corresponding output lines. To each output line, multiple individual blanking mechanisms 40 are connected in series.

For example, the selector 320 has eight output lines row1 to row8, and 256 individual blanking mechanisms 40 are connected to each output line. By arranging 64 selectors 320 in each of the input-output circuits 31a and 31b, the beam on-off signals can be transferred to 512×512 individual blanking mechanisms 40 in the cell array circuit 34.

The arrangement of the individual blanking mechanisms 40 to which the input-output circuit 31a outputs the beam on-off signal and the individual blanking mechanisms 40 to which the input-output circuit 31b outputs the beam on-off signal is not limited to that illustrated in FIG. 6. For example, the output lines from the input-output circuit 31a and the output lines from the input-output circuit 31b may be arranged in an alternating manner. Alternatively, the individual blanking mechanisms 40 to which the input-output circuit 31a outputs the beam on-off signal and the individual blanking mechanisms 40 to which the input-output circuit 31b outputs the beam on-off signal may be arranged in an alternating manner.

As illustrated in FIG. 7, each individual blanking mechanism 40 has a shift register 41, a pre-buffer 42, a buffer 43, a data register 44, a NAND circuit 45, and an amplifier 46. The shift register 41 transfers data output from the shift register of the previous cell to the shift register of the subsequent cell in accordance with a clock signal (SHIFT).

The pre-buffer 42 stores the beam on-off signal for the cell output from the shift register 41 in accordance with a clock signal (LOAD1).

The buffer 43 receives and holds the output value from the pre-buffer 42 in accordance with a clock signal (LOAD2).

The data register 44 receives and holds the output value from the buffer 43 in accordance with a clock signal (LOAD3).

To the NAND circuit 45, the output signal from the data register 44 and a blanking control signal (SHOT_ENABLE) are input. The output signal from the NAND circuit 45 is supplied to the electrode 51 of the blanker 50 via the amplifier 46 (a driver amplifier).

In a case where both the output signal from the data register 44 and the blanking control signal are high, the output from the NAND circuit 45 is low, the electrodes 51 and 52 are at the same potential, and the beam is thus on because the blanker 50 does not reflect the beam. In a case where at least one of the output signal from the data register 44 and the blanking control signal is low, the output from the NAND circuit 45 is high, the electrodes 51 and 52 are at different potentials, and the beam is thus off because the blanker 50 deflects the beam.

The blanking control signal is input to the NAND circuits 45 of all the individual blanking mechanisms 40. In a state where the blanking control signal is kept high, the beam is switched between on and off in accordance with the output from the data register 44. That is, the beam is on in a case where the irradiation time control data is 1 (high) and off in a case where the irradiation time control data is 0 (low).

In contrast, when the blanking control signal is low, regardless of whether the value of the irradiation time control data is high or low, all the blankers 50 deflect the beams and switch all the beams off in a collective manner.

The data processing unit 111 of the control computer 110 virtually divides the writing region 10 of the substrate 101 into multiple mesh regions. The sizes of the mesh regions are, for example, about the same size as one individual beam, and each mesh region is a pixel (a unit irradiation region). The data processing unit 111 reads out writing data from the memory unit 140 and calculates a pattern area density p for each pixel using the pattern defined in the writing data.

The data processing unit 111 calculates the irradiation dose of the beam with which each pixel is irradiated, by multiplying the pattern area density p by a reference irradiation dose and a correction coefficient for correcting proximity effects, for example. The data processing unit 111 calculates irradiation time by dividing the irradiation dose by the current density. The data processing unit 111 rearranges the irradiation time data in shot order according to the writing sequence to generate irradiation time control data.

The data transfer unit 113 outputs the irradiation time control data to the deflection control circuit 130. The writing controller 112 controls the individual units of the writing unit 150 to execute the writing process on the substrate 101.

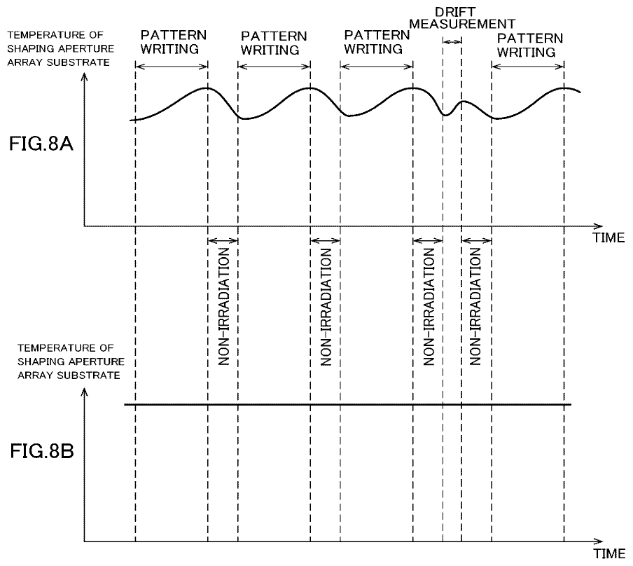

In existing writing apparatuses, irradiation time control data was transferred only during periods of beam irradiation in which a member in the writing chamber 103 is irradiated with beams, such as when a pattern is written on the substrate 101 and when drift measurement is performed in which the mark on the XY stage 105 is scanned. Data transfer was not performed during other time periods, which are periods of beam non-irradiation, such as a period from the completion of writing on one stripe region 12 to moving to the next stripe region 12 and when the substrate 101 is transported (into and out of the writing chamber 103). As illustrated in FIG. 8A, circuit currents (a power supply current and operating currents based on the beam on-off signals and other signals) flow through the input-output circuits 31a and 31b and the cell array circuit 34 of the blanking aperture array substrate 204 only during periods of beam irradiation in which data transfer is performed. This generates a large amount of heat and results in an increase in the temperature of the shaping aperture array substrate 203. In contrast, during periods of beam non-irradiation in which data transfer is not performed, the circuit currents do not flow (the amounts of currents are small). This generates a small amount of heat and results in a reduction in the temperature of the shaping aperture array substrate 203. In this manner, the amount of heat generated by the blanking aperture array substrate 204 was not constant before, and the temperature of the shaping aperture array substrate 203 was not stable.

Thus, in the present embodiment, the irradiation time control data is transferred even during periods of beam non-irradiation to cause circuit currents to flow to the input-output circuits 31a and 31b and the cell array circuit 34 of the blanking aperture array substrate 204. In this case, to prevent the beams from reaching the substrate 101, the blanking controller 114 controls the collective deflector 209 to switch all the beams off in a collective manner. Alternatively, the blanking controller 114 may set the blanking control signals low to switch all the beams off in a collective manner.

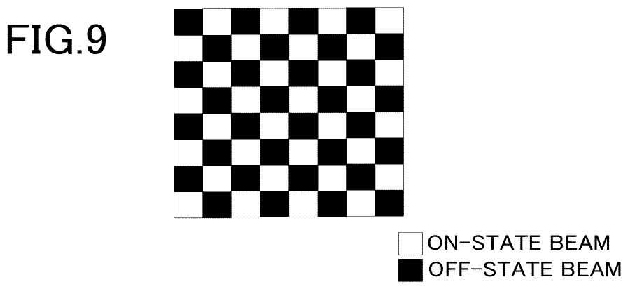

The irradiation time control data transferred by the data transfer unit 113 during periods of beam non-irradiation is not particularly limited; however, for example, data can be used in which on-state beams and off-state beams are arranged vertically and horizontally in an alternating manner in plan view as illustrated in FIG. 9. Data for switching all the beams off and data for switching all the beams on may be transferred. The irradiation time control data transferred during the periods of beam non-irradiation may be of a single type, or multiple types of data may be switched.

In this manner, by continuously transferring data to the blanking aperture array substrate 204, the operating currents for the blanking aperture array substrate 204 become constant, and the radiation heat to the shaping aperture array substrate 203 becomes also constant. Note that hereinafter, “constant” does not necessarily mean the same value, and fluctuations are allowed within a range that does not affect the writing accuracy. In this manner, by keeping the operating currents constant, the temperature of the shaping aperture array substrate 203 can be stabilized, as illustrated in FIG. 8B. Deformation of the shaping aperture array substrate 203 is suppressed, and beam position fluctuations can be reduced. In addition, the interval between beam drift measurements can be increased, so that the throughput of the writing process can be improved.

In the writing apparatus 100, in a case where the pattern density of the pattern to be written is high, the blanking count of the blankers 50 (the number of times switching occurs between beam on and off) increases, the power consumption of the blanking aperture array substrate 204 increases, and the radiation heat to the shaping aperture array substrate 203 becomes higher, compared with the case where a sparse pattern is to be written. As the difference in blanking count between the stripe regions 12 increases, the difference in the radiant heat to the shaping aperture array substrate 203 increases, and the temperature fluctuations of the shaping aperture array substrate 203 become larger. After careful consideration, the present inventors found that the radiation heat to the shaping aperture array substrate 203 becomes constant when the blankers 50 perform blanking during periods of beam non-irradiation such that the difference in blanking count between the stripe regions 12 is reduced, so that the temperature of the shaping aperture array substrate 203 can be stabilized.

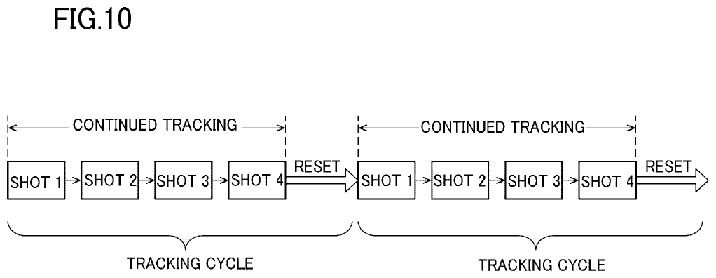

As mentioned above, in the writing method in which writing is performed while moving the XY stage 105, tracking is continued during the irradiation of n shots (n pixels are exposed), and tracking reset is performed after the irradiation of n shots. In the example in FIG. 4, n=4. In this case, as illustrated in FIG. 10, one tracking cycle is constituted by the irradiation of four shots, in which four pixels are written while tracking continues, followed by a tracking reset.

Blanking for adjusting the blanking count is performed during the tracking reset. The tracking reset is a timing at which the substrate 101 is not irradiated with beams, and thus the blanking controller 114 controls the collective deflector 209 to switch all the beams off in a collective manner such that the beams do not reach the substrate 101.

During the tracking reset, the data for switching all the beams off and the data for switching all the beams on are transferred in an alternating manner, so that the blankers 50 switch the beams between on and off to adjust the blanking count. Alternatively, after transferring the data for switching all the beams on and setting the output of the data register 44 high, the blankers 50 may switch the beams between on and off to adjust the blanking count by switching the value of the blanking control signal between high and low.

A writing operation for a writing layout to be evaluated is performed in advance, and the operating currents per tracking cycle of the input-output circuits 31a and 31b of the blanking aperture array substrate 204 are recorded in a memory (not illustrated) during the writing process, and the data processing unit 111 obtains a maximum value I_{MAX} of the operating currents per tracking cycle. The operating currents can be detected by ammeters provided in the input-output circuits 31a and 31b. During the writing process, for each stripe region 12, the data processing unit 111 measures a blanking count Ns and a tracking cycle count Nt, and records them in the memory.

A table in which the blanking count per tracking cycle for the blanking aperture array substrate 204 (the total blanking count of all the blankers) is associated with the operating currents of the input-output circuits 31a and 31b is prepared and is stored in the memory.

The data processing unit 111 refers to the table to acquire a blanking count Nb per tracking cycle corresponding to the operating current I_{MAX}. This blanking count Nb is a target blanking count per tracking cycle.

The data processing unit 111 divides the blanking count Ns by the tracking cycle count Nt to obtain an average blanking count Ns/Nt per tracking cycle. The data processing unit 111 then calculates the difference (Nb−Ns/Nt) between the target blanking count Nb per tracking cycle and the average blanking count Ns/Nt.

By performing blanking (Nb−Ns/Nt) times during the tracking reset, the blanking count becomes almost equal to the target count Nb for all tracking cycles for all the stripe regions 12, and the radiation heat to the shaping aperture array substrate 203 becomes constant. Thus, the temperature of the shaping aperture array substrate 203 can be stabilized.

In the embodiment described above, the example has been described in which the blanking aperture array substrate has two input-output circuits, and the data paths from the deflection control circuit 130 are divided into two systems; however, the number of input-output circuits may be three or more, and the data paths from the deflection control circuit 130 may be three or more systems. Moreover, data paths for two or more systems may be input from the deflection control circuit 130 to a single input-output circuit.

Temperature stabilization is not limited to the shaping aperture array substrate 203. The temperature of an multi-beam emission unit provided above the blanking aperture array substrate can be stabilized, regardless of the method used to form multiple charged-particle beams.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A multiple charged-particle beam writing method comprising:
emitting multiple charged-particle beams;
switching predetermined beams of the multiple charged-particle beams between on and off using a plurality of blankers provided on a blanking aperture array substrate; and
transferring, while moving a stage installed in a writing chamber, control data for on-off control of each beam of the multiple charged-particle beams to a control circuit of the blanking aperture array substrate to irradiate a writing target substrate placed on the stage with the multiple charged-particle beams based on the control data and write a pattern,
wherein the control circuit is operated during a period of beam non-irradiation in which the writing target substrate is not irradiated with the multiple charged-particle beams.

2. The multiple charged-particle beam writing method according to claim 1, wherein the control circuit is operated such that fluctuations in an amount of current flowing through the control circuit falls within a predetermined range.

3. The multiple charged-particle beam writing method according to claim 1, wherein during the period of beam non-irradiation, the control circuit is operated by at least transferring the control data or switching the predetermined beams between on and off.

4. The multiple charged-particle beam writing method according to claim 3, wherein the control circuit is operated such that at least transfer of a predetermined amount of the control data or a predetermined number of times of switching the beams between on and off is performed throughout a period of beam irradiation, in which the writing target substrate is irradiated with the multiple charged-particle beams, and the period of beam non-irradiation.

5. The multiple charged-particle beam writing method according to claim 1, wherein during the period of beam non-irradiation, all the multiple beams are deflected in a collective manner using a collective deflector to switch all the beams off.

6. The multiple charged-particle beam writing method according to claim 1, wherein during the period of beam non-irradiation, the plurality of blankers are set to be in a beam-off state, regardless of a value of the control data.

7. The multiple charged-particle beam writing method according to claim 1, wherein the period of beam non-irradiation includes at least one of a timing at which tracking control for deflecting the multiple charged-particle beams so as to follow movement of the stage is reset, a period from a completion of a writing process on a single stripe region to a start of a subsequent writing process, and a period for transporting the writing target substrate.

8. A multiple charged-particle beam writing apparatus comprising:
an emission unit that emits multiple charged-particle beams;
a blanking aperture array substrate having a plurality of blankers that correspond to the respective beams of the multiple charged-particle beams and each switch a corresponding one of the beams between on and off;
a movable stage that is installed in a writing chamber and on which a writing target substrate is placed that is to be irradiated with the multiple charged-particle beams;
a data transfer unit that transfers control data for on-off control of each beam of the multiple charged-particle beams to a control circuit of the blanking aperture array substrate; and
a control unit that controls the plurality of blankers and the data transfer unit,
wherein the control unit causes the control circuit to operate during a period of beam non-irradiation in which the writing target substrate is not irradiated with the multiple charged-particle beams.

9. The multiple charged-particle beam writing apparatus according to claim 8, wherein the control unit causes the control circuit to operate such that fluctuations in an amount of current flowing through the control circuit falls within a predetermined range.

10. The multiple charged-particle beam writing apparatus according to claim 8, wherein during the period of beam non-irradiation, the control unit causes the control circuit to operate by at least transferring the control data or switching the predetermined beams between on and off.

11. The multiple charged-particle beam writing apparatus according to claim 10, wherein the control unit causes the control circuit to operate such that at least transfer of a predetermined amount of the control data or a predetermined number of times of switching the beams between on and off is performed throughout a period of beam irradiation, in which the writing target substrate is irradiated with the multiple charged-particle beams, and the period of beam non-irradiation.

12. The multiple charged-particle beam writing apparatus according to claim 8, further comprising a collective deflector deflecting all the multiple beams in a collective manner to switch all the beams off during the period of beam non-irradiation.

13. The multiple charged-particle beam writing apparatus according to claim 8, wherein during the period of beam non-irradiation, the control unit sets the plurality of blankers in a beam-off state, regardless of a value of the control data.

14. The multiple charged-particle beam writing apparatus according to claim 8, wherein the period of beam non-irradiation includes at least one of a timing at which tracking control for deflecting the multiple charged-particle beams so as to follow movement of the stage is reset, a period from a completion of a writing process on a single stripe region to a start of a subsequent writing process, and a period for transporting the writing target substrate.
